(19) United States
(12) Patent Application Publication
(10) Pub. No.: US 2025/0038098 A1
(43) Pub. Date: Jan. 30, 2025

(54) TERMINAL, METHOD FOR MANUFACTURING TERMINAL, AND SEMICONDUCTOR DEVICE

(71) Applicant: FUJI ELECTRIC CO., LTD., Kawasaki-shi (JP)

(72) Inventor: Tomomi NONAKA, Kawasaki-shi (JP)

(73) Assignee: FUJI ELECTRIC CO., LTD., Kawasaki-shi (JP)

(21) Appl. No.: 18/678,874

(22) Filed: May 30, 2024

(30) Foreign Application Priority Data
Jul. 26, 2023 (JP) 2023-121412

(51) Int. Cl. H01L 23/498; H01L 23/495

(52) U.S. Cl. CPC H01L 23/49844; H01L 23/4952; H01L 23/49822

(57) ABSTRACT

A terminal includes a plate-like first terminal component having a through hole and a second terminal component having a columnar portion at an end thereof. The columnar portion extends through the through hole and is exposed outside the first terminal component. The second terminal component is mechanically joined to the first terminal component at the columnar portion, which has plastic deformation. An outer surface of the columnar portion contacts an inner surface of the first terminal component that bounds the through hole. The through hole has a polygonal cross section orthogonal to an axis of the columnar portion.

### CROSS-REFERENCE TO RELATED APPLICATION

This application is based upon and claims the benefit of priority to Japanese Patent Application No. 2023-121412, filed on Jul. 26, 2023, the entire contents of which are incorporated herein by reference.

### BACKGROUND OF THE INVENTION

### 1. Technical Field

The present invention relates to a terminal, a manufacturing method for manufacturing a terminal, and a semiconductor device including the terminal.

### 2. Description of the Related Art

In the related art, a method for joining a shaft member to a substrate by caulking has been proposed (refer to, for example, JP H03-018444 A).

### SUMMARY OF THE INVENTION

Here, in order to manufacture a terminal having a complicated shape such as a shape having a shaft-like portion and a plate-like portion, it is conceivable to caulk and join a plurality of terminal components.

However, when a cylindrical portion of one terminal component is inserted into a circular through hole of another terminal component and caulking and joining is performed at a tip of the cylindrical portion, in a case where rotational torque is applied to the terminal component, slippage occurs on a close contact surface between the circular through hole and the cylindrical portion, and the terminal component rotates.

An object of the present invention is to provide a terminal, a method for manufacturing a terminal, and a semiconductor device capable of increasing the strength of a caulked and joined terminal with respect to rotational torque.

In one aspect, a terminal includes a first terminal component having a through hole and a second terminal component having a columnar portion inserted into the through hole, the second terminal component is caulked and joined to the first terminal component at a tip of the columnar portion, the columnar portion is in contact with a wall surface of the through hole, and a cross section of the through hole orthogonal to an insertion direction of the columnar portion is polygonal.

In another aspect, a method for manufacturing a terminal is a manufacturing method for manufacturing a terminal, the terminal including a first terminal component having a through hole and a second terminal component having a columnar portion inserted into the through hole, the method including: inserting the columnar portion of the second terminal component into the through hole having a polygonal cross section orthogonal to an insertion direction of the columnar portion; and bringing the columnar portion into contact with a wall surface of the through hole by caulking and joining the second terminal component to the first terminal component at a tip of the columnar portion inserted into the through hole.

In another aspect, a semiconductor device includes a terminal including a first terminal component having a through hole and a second terminal component having a columnar portion inserted into the through hole; a semiconductor element electrically connected to the terminal; and a case which is integrally molded with the terminal in a state where a part of the terminal is exposed and accommodates the semiconductor element, in which the second terminal component is caulked and joined to the first terminal component at a tip of the columnar portion and the columnar portion is in contact with a wall surface of the through hole, and a cross section of the through hole orthogonal to an insertion direction of the columnar portion is polygonal.

According to the above aspect, it is possible to increase the strength of the caulked and joined terminal with respect to the rotational torque.

### BRIEF DESCRIPTION OF THE DRAWINGS

FIG. 1 is a cross-sectional view illustrating a semiconductor device in an embodiment;

FIGS. 2A to 2C are plan views and cross-sectional views (part 1) illustrating a method for manufacturing a terminal according to an embodiment;

FIGS. 3A to 3C are plan views and cross-sectional views (part 2) illustrating a method for manufacturing a terminal according to the embodiment;

FIGS. 4A to 4H are views illustrating examples of a shape of a through hole of a first terminal component according to an embodiment; and

FIG. 5 is a table showing evaluation results of Examples 1 to 4 and Comparative Examples 1 to 4.

### DETAILED DESCRIPTION

Hereinafter, a terminal, a method for manufacturing a terminal, and a semiconductor device according to an embodiment of the present invention will be described with reference to the drawings. Note that the present invention is not limited to the embodiment described below, and can be appropriately modified and implemented within the scope not changing the gist thereof.

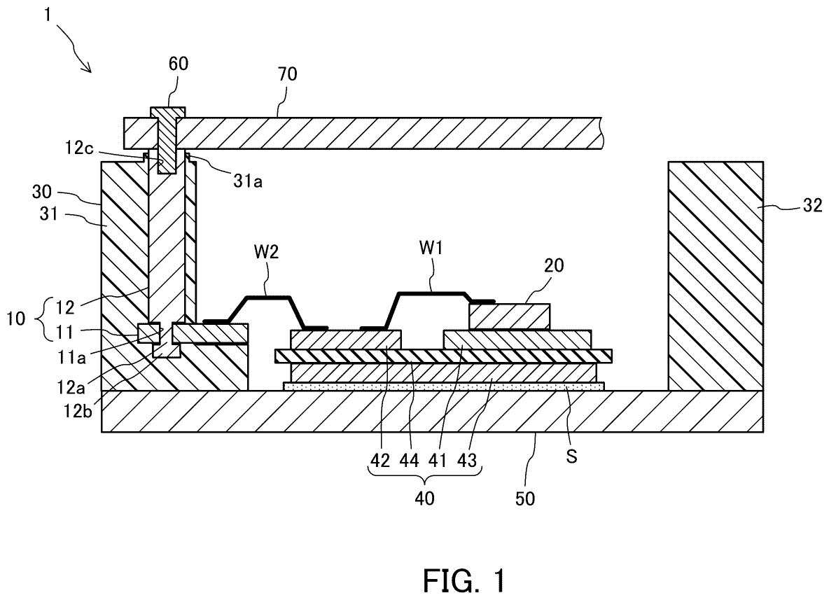

FIG. 1 is a cross-sectional view illustrating a semiconductor device 1.

An example in which a terminal is used in a semiconductor device will be described. A semiconductor device 1 illustrated in FIG. 1 includes the terminal 10, a semiconductor element 20, a case 30, a multi-layer substrate 40, a metal base 50, a screw 60, a wiring board 70, and wirings W1 and W2.

As an example, the semiconductor device 1 is applied to a power conversion device such as an inverter device of an industrial or in-vehicle motor together with a cooler (not shown) disposed below the metal base 50. In the following description, detailed description of the same or similar configuration, function, operation, assembly method, and the like as those of a known semiconductor device 1 will be omitted.

The terminal 10 includes a first terminal component 11 and a second terminal component 12 caulked and joined to the first terminal component 11. Note that caulking and joining (kashime in the Japanese language) refers to joining by caulking, and caulking is a processing method in which a certain force is applied to a plurality of members to plastically deform a part of the components to mechanically join the components.

The first terminal component 11 has a plate shape and has a through hole 11a penetrating through the first terminal component 11 in a thickness direction. Although the through hole 11a will be described in detail later, the cross-sectional shape of the through hole 11a is polygonal, and a columnar portion 12a of the second terminal component 12 is provided at one of two ends of the second terminal component 12, and an outer circumferential surface of the columnar portion 12a is in contact with a wall surface (inner surface) of the first terminal component that bounds the through hole 11a (the wall surface inside the first terminal component 11 constituting the through hole 11a). The first terminal component 11 is, for example, a metal material formed of a metal raw material such as a copper material, a copper alloy-based material, an aluminum alloy-based material, or an iron alloy-based material, and is electrically connected to a second conductor plate 42 by the wiring W2. The second conductor plate 42 is electrically connected to the semiconductor element 20 by the wiring W1. Therefore, it can be said that the first terminal component 11 (terminal 10) is electrically connected to the semiconductor element 20. The wirings W1 and W2 are, for example, lead frames or wires. In addition, the first terminal component 11 is not limited to a plate shape spreading horizontally, and may have, for example, a plate shape having a bent portion bent at 90 degrees, or another shape such as a shape other than the plate shape.

The second terminal component 12 has a cylindrical shaft shape and has the columnar portion 12a provided at one end (lower end in FIG. 1). The columnar portion 12a is, for example, a cylindrical portion having a cylindrical shape having a smaller diameter than other portions. A caulked joint portion 12b that is plastically deformed by caulking processing is provided at the tip of the columnar portion 12a. The second terminal component 12 is caulked and joined to the first terminal component 11 at the caulked joint portion 12b. Therefore, the second terminal component 12 may be referred to as a caulking component, and the first terminal component 11 may be referred to as a caulked component. Specifically, the second terminal component 12 is mechanically joined to the first terminal component 11 at the columnar portion 12a that is inserted in the through hole 11a and a tip portion of the columnar portion 12a is exposed outside the first terminal component. The columnar portion 12a including the caulked joint portion 12b has plastic deformation, the columnar portion 12a is in direct contact with the inner surface of the first terminal component that bounds the through hole 11a, and the caulked joint portion 12b is in direct contact with an outer surface of the first terminal component 11 at an area surrounding the through hole, so that the columnar portion 12a is bound by said inner surface, thereby to mechanically join the first terminal component 11 and the second terminal component 12 to each other without using any other elements such as a screw or a rivet.

As an example, the second terminal component 12 may have a female screw hole 12c at an end portion (upper end in FIG. 1) opposite to the columnar portion 12a (caulked joint portion 12b). The second terminal component 12 is made of, for example, a metal material such as copper, brass, or stainless steel plated with nickel, and is electrically connected to the wiring board 70 by the screw 60 in the female screw hole 12c.

The shapes of the first terminal component 11 and the second terminal component 12 are not particularly limited. The materials of the first terminal component 11 and the second terminal component 12 may be the same material. The columnar portion 12a of the second terminal component 12 is not limited to the cylindrical portion, and may be a polygonal columnar portion having a polygonal columnar shape.

The semiconductor element 20 is joined onto a first conductor plate 41 by a conductive joining material (not shown) such as solder. The semiconductor element 20 is formed of, for example, a reverse conducting (RC)-insulated gate bipolar transistor (IGBT) element obtained by integrating an IGBT element that is a switching element and a diode element such as a free wheeling diode (FWD) element or the like connected to the IGBT element and the switching element in an inverse parallel manner. The switching element and the diode element in the semiconductor element 20 are not limited to be formed on a Si substrate, and may be formed on a semiconductor substrate using a wide band gap semiconductor such as silicon carbide (SiC) or gallium nitride (GaN), for example. This type of semiconductor element 20 is provided with electrodes (not shown) on a lower surface and an upper surface. The semiconductor element 20 is electrically connected to the above-described wiring W1 by a conductive joining material at an electrode provided on the upper surface. Although not shown, the semiconductor element 20 may be electrically connected to a main terminal such as an output terminal and an input terminal (P terminal and N terminal) provided in the case 30, a control terminal, and the like directly by wiring (not shown) or indirectly via the first conductor plate 41 and the second conductor plate 42.

The case 30 has a quadrangular cylindrical shape integrally including a left side wall 31, a right side wall 32, and a front wall and a rear wall (not shown), and accommodates the semiconductor element 20. The case 30 is formed, for example, using an insulating resin material such as poly phenylene sulfide (PPS) or poly amide (PA). The case 30 is bonded to the upper surface of the metal base 50.

The case 30 (left side wall 31) is integrally molded with the terminal 10 in a state where a part (female screw hole 12c of second terminal component 12 and/or a joint portion of first terminal component 11 with wiring W2) of the terminal 10 is exposed. In other words, the terminal 10 is insert-molded in the case 30. Note that the caulked portion (caulked joint portion 12b) between the first terminal component 11 and the second terminal component 12 may be covered with the resin that is the material of the case 30, or may be partially or entirely exposed. Since the caulked portion is fixed by the resin when covered with the resin, the fastening property between the first terminal component 11 and the second terminal component 12 is improved. A cylindrical protrusion 31a protruding upward so as to support the upper end of the second terminal component 12 is integrally provided at the upper end of the left side wall 31. The semiconductor element 20, the first conductor plate 41, the second conductor plate 42, and the like in the case 30 are sealed with a sealing material (not shown). The sealing material is an epoxy resin, silicone gel, or the like, for example.

The multi-layer substrate 40 includes the first conductor plate 41, the second conductor plate 42, a third conductor plate 43, and an insulating substrate 44. The first conductor plate 41 and the second conductor plate 42 are provided on the upper surface of the insulating substrate 44, and the third conductor plate 43 is provided on the lower surface of the insulating substrate 44. The multi-layer substrate 40 is, for example, a direct copper bonding (DCB) substrate or an active metal brazing (AMB) substrate.

The first conductor plate 41 and the second conductor plate 42 are members that function as a wiring member in the inverter circuit and are formed of, for example, a metal plate, a metal foil, or the like of copper, aluminum, or the like. The first conductor plate 41 and the second conductor plate 42 may be also referred to as a conductor layer, a conductive layer, a conductor pattern, a wiring pattern, or the like.

The third conductor plate 43 is a member that functions as a heat conducting member for conducting heat generated in the inverter circuit to the metal base 50 and is formed of, for example, a metal plate, a metal foil, or the like of copper, aluminum, or the like. The third conductor plate 43 is bonded to the metal base 50 by a joining material S such as solder. The third conductor plate 43 may be also referred to as a heat dissipation layer, a heat dissipation plate, a conductor pattern, a heat dissipation pattern, or the like.

The insulating substrate 44 is not limited to a specific substrate. The insulating substrate 44 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 44 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The metal base 50 is a rectangular plate-like member. The metal base 50 is a member that functions as a heat conducting member that conducts heat generated by the semiconductor element 20 to the cooler (not shown), and is formed of a metal plate such as a copper plate or an aluminum plate, for example. The metal base 50 and the cooler are connected via a thermal conductive material such as a thermal grease or a thermal compound. The metal base 50 may have a function of a cooler.

As described above, the screw 60 is inserted into the female screw hole 12c of the second terminal component 12 to electrically and physically connect the wiring board 70 and the second terminal component 12 (terminal 10).

The wiring board 70 is disposed above the case 30. The wiring board 70 is an example of a member electrically connected to the terminal 10. This member may be a lead frame or another member such as an external conductor connected to the semiconductor device 1.

In the above description, the case where the terminal 10 is disposed in the semiconductor device 1 and electrically connected to the semiconductor element 20 has been described as an example, but the application of the terminal 10 is not limited to the semiconductor device 1, and may be used in any device. In addition, a circuit of the semiconductor device 1 described above includes a switching element, a diode element, and the like inside the semiconductor element 20, and the semiconductor device 1 may constitute any circuit such as a single-phase voltage half-bridge inverter circuit, a single-phase full-bridge inverter circuit, or a three-phase AC inverter circuit.

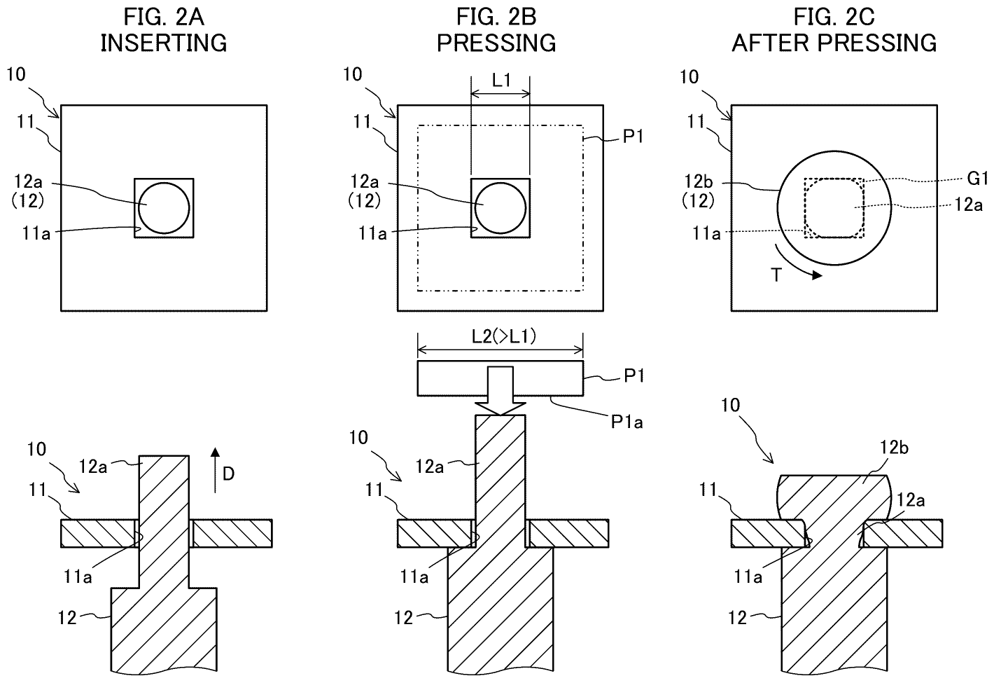

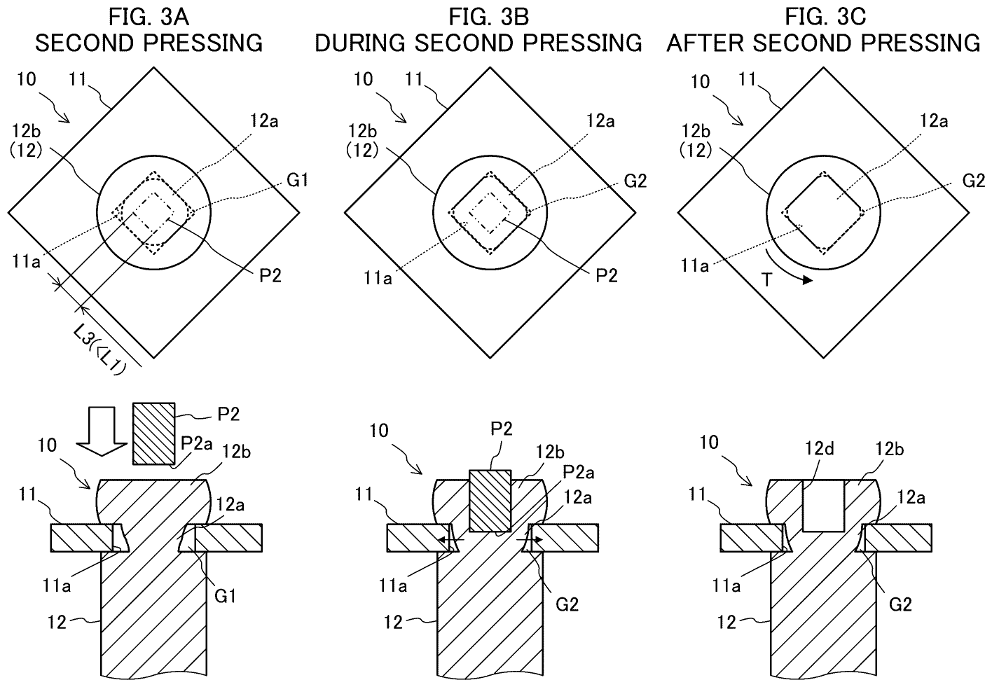

Next, a method for manufacturing the terminal 10 will be described with reference to FIGS. 2A to 2C and 3A to 3C. In FIGS. 2A to 2C and FIGS. 3A to 3C, a plan view is illustrated on the upper side, and a cross-sectional view is illustrated on the lower side. Note that the terminal 10 in the cross-sectional views of FIGS. 2A to 2C and 3A to 3C is vertically inverted from the terminal 10 in the cross-sectional view of FIG. 1. In FIGS. 2A to 2C and 3A to 3C, the shape of the first terminal component 11 is represented by a square, but as described above, the first terminal component 11 can have any shape.

First, as illustrated in FIG. 2A, the columnar portion 12a of the second terminal component 12 is inserted into the through hole 11a of the first terminal component 11 in an insertion direction D which is a central axis direction of the through hole 11a (longitudinal direction of the columnar portion 12a).

Then, as illustrated in FIG. 2B, a first pressing member P1 (illustrated by a two-dot chain line in the plan view of the upper view) which is, for example, a quadrangular prism-shaped punch presses the tip of the columnar portion 12a inserted into the through hole 11a in the direction opposite to the insertion direction D, thereby caulking and joining the second terminal component 12 to the first terminal component 11 (first pressing). Here, a pressing surface P1a of the first pressing member P1 is desirably larger than the cross section of the through hole 11a (or the columnar portion 12a) orthogonal to the insertion direction D. In the example of FIG. 2B, the cross-sectional shapes of the pressing surface P1a and the through hole 11a are square, and the length L2 of one of the four sides of the pressing surface P1a is longer than the length L1 of one of the four sides of the through hole 11a (L2>L1).

As illustrated in FIG. 2C, the tip of the columnar portion 12a of the second terminal component 12 becomes a caulked joint portion 12b that expands more than the through hole 11a (illustrated by a broken line (hidden line) together with the columnar portion 12a) by pressing using the first pressing member P1. By the pressing (caulking joining) of the first pressing member P1, the columnar portion 12a comes into contact with each wall surface of the through hole 11a, expands in the through hole 11a along each surface, and comes into close contact with each surface of the through hole 11a. In addition, the columnar portion 12a enters a corner portion of the through hole 11a like a wedge-shaped protrusion, and a gap G1 between the columnar portion 12a and the corner portion of the through hole 11a becomes small. As a result, for example, when the screw 60 is fastened to the female screw hole 12c illustrated in FIG. 1, even if the rotational torque T is applied to the second terminal component 12 in a state where the first terminal component 11 is fixed to the case 30 or the like (counterclockwise in the upper view of FIG. 2C), the columnar portion 12a is caught by each surface of the through hole 11a, so that the strength of the terminal 10 with respect to the rotational torque T increases. Note that the caulking and joining in the present embodiment is not limited to pressing the columnar portion 12a in the direction opposite to the insertion direction D into the through hole 11a, and other methods such as a method for pressing the columnar portion 12a from other directions may be used as long as the tip of the columnar portion 12a is plastically deformed.

Even after the columnar portion 12a is pressed by the first pressing member P1 described above, there may be the gap G1 between the corner portion of the through hole 11a and the columnar portion 12a. In FIGS. 3A to 3C, in order to represent the gap G1 (G2) also in the cross-sectional view of the lower view, the plan view of the upper view and the cross-sectional view of the lower view are represented by being inclined by 45 degrees with respect to FIGS. 2A to 2C.

In order to reduce the gap G1 between the corner portion of the through hole 11a and the columnar portion 12a, as illustrated in FIG. 3A, a second pressing member P2 (illustrated by a two-dot chain line in the plan view of the upper view), which is, for example, a quadrangular prism-shaped punch, may press the caulked joint portion 12b (the tip of the columnar portion 12a inserted into the through hole 11a) toward the through hole 11a (second pressing). Here, a pressing surface P2a of the second pressing member P2 is desirably smaller than the cross section of the through hole 11a (or the caulked joint portion 12b) orthogonal to the insertion direction D. In the example of FIG. 3A, the cross-sectional shapes of the pressing surface P2a and the through hole 11a are square, and the length L3 of one of the four sides of the pressing surface P2a is shorter than the length L1 of one of the four sides of the through hole 11a (L3<L1). The center of the pressing surface P2a desirably coincides with the center of the caulked joint portion 12b.

Preferably, the pressing surface P2a of the second pressing member P2 is a polygon (for example, a square) having a shape similar to the polygon of the cross section of the through hole 11a, and the corner portion of the pressing surface P2a may press the columnar portion 12a (caulked joint portion 12b) toward the through hole 11a in a direction coinciding with the corner portion of the through hole 11a in a virtual plane orthogonal to the insertion direction D.

As a result, as illustrated in FIG. 3B, the wedge-shaped protrusion of the columnar portion 12a entering the corner portion of the through hole 11a extends, so that the columnar portion 12a easily enters the depth of the corner portion of the through hole 11a, and the gap G2 between the corner portion of the through hole 11a and the columnar portion 12a after being pressed by the second pressing member P2 becomes small and is filled. Thereafter, as illustrated in FIG. 3C, the second pressing member P2 is extracted from the caulked joint portion 12b, and since the second pressing member P2 is extracted, a recess 12d is formed in the caulked joint portion 12b.

As described above, since the gap G2 between the corner portion of the through hole 11a and the columnar portion 12a after being pressed by the second pressing member P2 becomes small, even if the rotational torque T is applied to the second terminal component 12, the columnar portion 12a is caught almost entirely in the vicinity of the corner portion of each surface of the through hole 11a, so that the strength of the terminal 10 against the rotational torque T is further increased.

Here, as illustrated in the cross-sectional view of FIG. 3B, the second pressing member P2 may press the columnar portion 12a in a state of entering the inside of the through hole 11a. That is, the second pressing member P2 preferably presses the columnar portion 12a (caulked joint portion 12b) to a position where at least a part (pressing surface P2a or the like) reaches the through hole 11a (from the upper surface to the lower side of the first terminal component 11 in the lower view of FIG. 3B). As a result, the gap G2 between the corner portion of the through hole 11a and the columnar portion 12a becomes small, and is easily filled. When the second pressing member P2 enters the through hole 11a as described above, the recess 12d from which the second pressing member P2 has been extracted is also formed over the inside of the through hole 11a. When the length L3 of one side of the pressing surface P2a is too short, the columnar portion 12a is less likely to enter the depth of the corner portion of the through hole 11a. Therefore, as an example, the area of the pressing surface P2a is preferably half or more of the cross-sectional area of the through hole 11a.

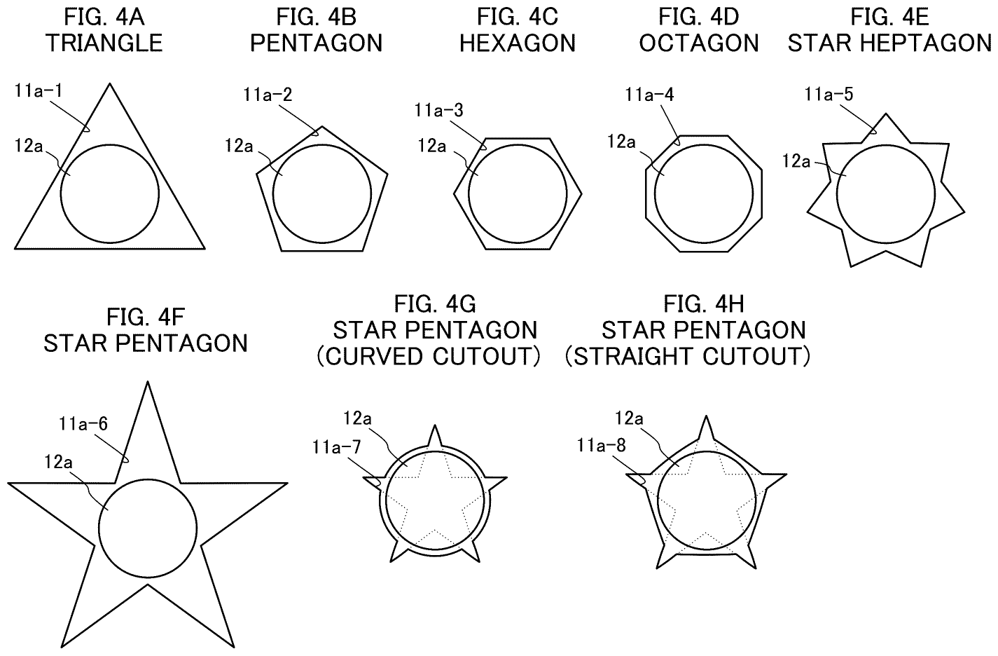

FIGS. 4A to 4H are views illustrating examples of a shape of the through hole 11a of the first terminal component 11.

Examples of the cross-sectional shape (the shape of the cross section orthogonal to the insertion direction D) of the through hole 11a include a triangle (for example, an equilateral triangle) such as a through hole 11a-1 illustrated in FIG. 4A, a pentagon (for example, a regular pentagon) such as a through hole 11a-2 illustrated in FIG. 4B, a hexagon (for example, a regular hexagon) such as a through hole 11a-3 illustrated in FIG. 4C, and an octagon (for example, a regular octagon) such as a through hole 11a-4 illustrated in FIG. 4D. As described above, as the cross-sectional shape of the through hole 11a, any shape can be adopted as long as it has a portion that is caught by the columnar portion 12a when the rotational torque T is applied to the second terminal component 12. However, in the through hole 11a-1 having a triangular cross-sectional shape illustrated in FIG. 4A, a joint area with the columnar portion 12a tends to be small as compared with the through hole 11a having a quadrangular cross-sectional shape illustrated in FIG. 2A. Therefore, from the viewpoint of increasing the joint area, it is desirable to use another through hole 11a such as the through hole 11a having a quadrangular cross-sectional shape than the through hole 11a-1 having a triangular cross-sectional shape.

In addition, examples of the cross-sectional shape of the through hole 11a other than the quadrangles as shown in FIGS. 2A to 2C and 3A to 3C include a star heptagon such as a through hole 11a-5 shown in FIG. 4E, a star pentagon such as a through hole 11a-6 shown in FIG. 4F, a shape obtained by cutting out a portion excluding corner portions of the star pentagon with a curve forming a single virtual circle such as a through hole 11a-7 shown in FIG. 4G, and a shape obtained by cutting out a portion excluding corner portions of the star pentagon with a straight line such as a through hole 11a-8 shown in FIG. 4H. In the through holes 11a-5 to 11a-8 having these star-shaped cross-sectional shapes, the anchor effect in a case where the columnar portion 12a enters the corner portion strongly acts. Note that the dotted line portions in FIGS. 4G and 4H are merely imaginary lines for representing the corner portions of the star pentagon.

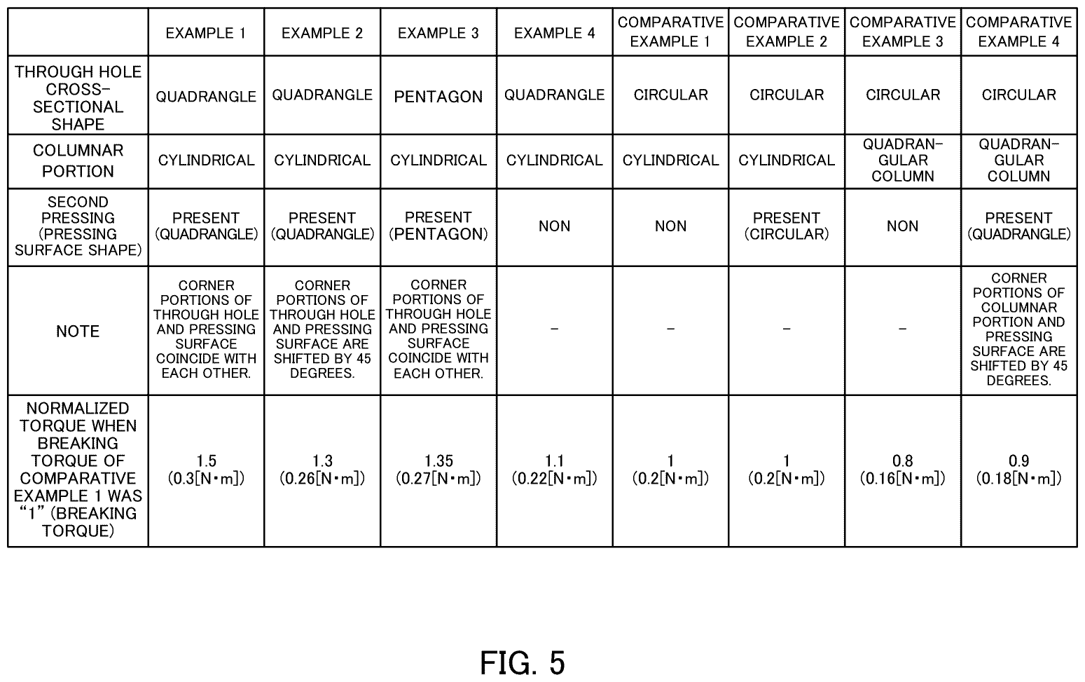

Next, evaluation results of Examples 1 to 4 and Comparative Examples 1 to 4 will be described with reference to the table of FIG. 5.

In Examples 1 to 4 and Comparative Examples 1 to 4, in the second terminal component 12, the diameter (the length of one side in Comparative Examples 3 and 4) of the columnar portion 12a was 1.5 mm, the diameter of the portion of the second terminal component 12 excluding the columnar portion 12a was 5 mm, and the length of the columnar portion 12a before pressing was 2.8 mm. Pressing was performed such that the diameter of the caulked joint portion 12b after pressing was 2.4 mm, and the length of the caulked joint portion 12b (portion extending from the through hole 11a) after pressing was 0.7 mm. The thickness of the first terminal component 11 was 0.8 mm, and the width of the first terminal component 11 in the lateral direction was 5 mm. That is, the caulking and joining were performed under the condition that the length (the diameter in Comparative Examples 1 to 4) of one side of the through hole 11a of the first terminal component 11 was larger than the diameter of the columnar portion 12a and smaller than the diameter of the caulked joint portion 12b. At that time, the second terminal component 12 was rotated, and the rotational torque T (breaking torque) until the second terminal component 12 and the first terminal component 11 after caulking and joining were separated was measured. Then, for Examples 1 to 4 and Comparative Examples 1 to 4, each breaking torque (normalized torque) when the breaking torque 0.2 [N·m] of Comparative Example 1 described later was 1 was calculated (normalized by the breaking torque value of Comparative Example 1).

First, as described above with reference to FIGS. 2A to 2C and 3A to 3C, Example 1 is an example in which the cross-sectional shape of the through hole 11a is quadrangular (square), the columnar portion 12a has a cylindrical shape, and the second pressing using the second pressing member P2 (the pressing surface P1a is quadrangular (square)) is performed. Then, in Example 1, the pressing by the second pressing member P2 is performed in a direction in which the corner portion of the pressing surface P2a of the second pressing member P2 coincides with the corner portion of the cross section of the through hole 11a. The breaking torque of Example 1 was 0.3 [N·m], and the normalized torque was 1.5. That is, the breaking torque (fastening force) was improved by 50% as compared with Comparative Example 1 which is one of the examples in the related art.

Next, Example 2 is the same as Example 1 except that pressing by the second pressing member P2 is performed in a direction in which the corner portion of the pressing surface P2a of the second pressing member P2 and the corner portion of the cross section of the through hole 11a are shifted by 45 degrees. The breaking torque of Example 2 was 0.26 [N·m], and the normalized torque was 1.3. Although it is improved by 30% as compared with Comparative Example 1, since the normalized torque of Example 2 is smaller than the normalized torque of Example 1, it can be said that it is desirable that the corner portion of the pressing surface P2a of the second pressing member P2 coincides with the corner portion of the cross section of the through hole 11a as in Example 1.

Next, Example 3 is the same as Example 1 except that the cross-sectional shape of the through hole 11a and the pressing surface P2a of the second pressing member P2 are not a quadrangle (square) but a pentagon (regular pentagon). The breaking torque of Example 3 was 0.27 [N·m], and the normalized torque was 1.35. When the number of corners of the through hole 11a is larger than that of the through hole 11a having a quadrangular cross-sectional shape in Example 1 as in the through hole 11a having a pentagonal cross-sectional shape in Example 3, it can be said that the columnar portion 12a is easily spread to the corner portion of the through hole 11a when the columnar portion 12a is crushed even if the pressing force of the second pressing member P2 is small, but the penetration of the columnar portion 12a into the corner portion of the through hole 11a is small. It is considered that when the number of corners of the through hole 11a is increased, the penetration of the columnar portion 12a into the corner portion of the through hole 11a decreases, and the cross-sectional shape of the through hole 11a approaches a perfect circular shape, so that the breaking torque decreases. However, when the cross-sectional shape of the through hole 11a is a polygon, the columnar portion 12a is plastically deformed and spreads at the corner portion of the polygon, and thus the breaking torque (fastening force) is improved as compared with Comparative Example 1.

Next, Example 4 is the same as Example 1 except that the second pressing by the second pressing member P2 is omitted. The breaking torque of Example 4 was 0.22 [N·m], and the normalized torque was 1.1. In Example 4, as compared with Example 1 in which the second pressing is applied, the gap between the columnar portion 12a and the corner portion of the through hole 11a becomes the gap G1 illustrated in FIG. 2C after the first pressing using the first pressing member P1, and can be said to be larger than the gap G2 illustrated in FIG. 3C after the second pressing using the second pressing member P2. Therefore, it can be said that the columnar portion 12a does not sufficiently enter the corner portion of the through hole 11a, and the breaking torque decreases. In addition, since the gap G1 after the first pressing is larger than the gap G2 after the second pressing, it can be said that the tensile strength of the second terminal component 12 in the axial direction becomes relatively low. However, even if the second pressing by the second pressing member P2 is omitted as in Example 4, the normalized torque is 1.1, and the breaking torque is increased by 10% as compared with Comparative Example 1 in which the cross-sectional shape of the through hole is circular and by 37.5% as compared with Comparative Example 3 to be described later, so that the effectiveness of the fact that the cross-sectional shape of the through hole 11a is polygonal can be confirmed. From the results of Examples 1 to 4 described above, it is found that the cross-sectional shape of the through hole 11a is preferably a quadrangular or pentagonal polygon.

Next, in Comparative Example 1, the cross-sectional shape of the through hole is different from that of Example 1 in a circular shape, and the second pressing is omitted. As described above, the breaking torque of Comparative Example 1 is 0.2 [N·m], and the normalized torque is 1. In Comparative Example 1, as compared with Example 1, it is considered that the breaking torque is relatively small because there is no penetration of the columnar portion 12a into the corner portion of the through hole, the through hole is circular and there is no surface that receives the rotation of the columnar portion 12a, and the like.

Next, Comparative Example 2 is the same as Comparative Example 1 except that the second pressing is performed. At the time of the second pressing in Comparative Example 2, the pressing surface P2a of the second pressing member P2 was changed to a circular shape. The breaking torque of Comparative Example 2 was 0.2 [N·m], and the normalized torque was 1. In Comparative Example 2, the second pressing was performed in addition to Comparative Example 1, but it was not possible to confirm a change in both the breaking torque and the tensile strength as compared with Comparative Example 1. This is considered to be because even when the second pressing is performed, since the cross-sectional shape of the through hole is circular, the columnar portion 12a does not enter the corner portion of the through hole, and the columnar portion 12a is not caught by the side surface (inner peripheral surface) of the through hole.

Comparative Example 3 is the same as Comparative Example 1 except that the columnar portion 12a is a quadrangular columnar portion. The breaking torque of Comparative Example 3 was 0.16 [N·m], and the normalized torque was 0.8. In Comparative Example 3, since a gap is formed between the through hole having a circular cross-sectional shape and the columnar portion 12a which is a quadrangular columnar portion and the contact area is reduced, it is considered that the breaking torque and the tensile strength are inferior to those of Comparative Example 1. In addition, since the corner portion of the quadrangular columnar portion penetrates into the circular through hole, cracking or the like is likely to occur. That is, it can be seen that the breaking torque is not improved when the cross-sectional shape of the through hole and the cross section orthogonal to the insertion direction D of the columnar portion 12a are opposite to those of Example 4.

Comparative Example 4 is the same as Comparative Example 3 except that a second pressing member P2 having a quadrangular pressing surface P2a is used. In Comparative Example 4, the corner portion of the columnar portion 12a and the corner portion of the pressing surface P2a are shifted by 45 degrees so as to fill the gap of Comparative Example 3. The breaking torque of Comparative Example 4 was 0.18 [N·m], and the normalized torque was 0.9. In Comparative Example 4, as compared with Comparative Example 3, the gap between the through hole having a circular cross-sectional shape and the columnar portion 12a which is a quadrangular columnar portion can be reduced, but since the gap remains, it is considered that the breaking torque is smaller than that in Comparative Example 1.

The terminal 10 according to the present embodiment described above includes the first terminal component 11 having the through hole 11a and the second terminal component 12 having the columnar portion 12a inserted into the through hole 11a. The second terminal component 12 is caulked and joined to the first terminal component 11 at the tip (caulked joint portion 12b) of the columnar portion 12a, the columnar portion 12a contacts the wall surface of the through hole 11a, and the through hole 11a has a polygonal cross section orthogonal to the insertion direction D of the columnar portion 12a.

Further, the method for manufacturing the terminal 10 according to the present embodiment is a manufacturing method of a terminal 10 for manufacturing the terminal 10 including the first terminal component 11 having the through hole 11a and the second terminal component 12 having the columnar portion 12a inserted into the through hole 11a, the method including: inserting the columnar portion 12a of the second terminal component 12 into the through hole 11a having a polygonal cross section orthogonal to the insertion direction D of the columnar portion 12a (insertion step illustrated in FIG. 2A); and caulking and joining the second terminal component 12 to the first terminal component 11 at the tip (caulked joint portion 12b) of the columnar portion 12a inserted into the through hole 11a, bringing the columnar portion 12a into contact with a wall surface of the through hole 11a (increase the contact area) (pressing step (caulking joining step) illustrated in FIGS. 2B and 2C).

In addition, the semiconductor device 1 according to the present embodiment includes the above-described terminal 10, the semiconductor element 20 electrically connected to the terminal 10, and the case 30 integrally molded with the terminal 10 in a state where a part (for example, the female screw hole 12c of the second terminal component 12 and the joint portion with the wiring W2 of the first terminal component 11) of the terminal 10 is exposed and accommodating the semiconductor element 20.

In the terminal 10, the method for manufacturing the terminal 10, and the semiconductor device 1, the cross-sectional shape of the through hole 11a of the first terminal component 11 is polygonal. As a result, the columnar portion 12a of the second terminal component 12 expands in the through hole 11a along each surface of the through hole 11a, and is in close contact with each surface of the through hole 11a. In addition, since the columnar portion 12a enters the corner portion of the through hole 11a like a wedge-shaped protrusion, the columnar portion 12a is firmly fixed to the through hole 11a, and an anchor effect acts on the wedge-shaped protrusion of the columnar portion 12a. Even when the rotational torque T is applied to the terminal 10 (for example, the second terminal component 12), the columnar portion 12a is caught on each surface of the through hole 11a, frictional resistance between the columnar portion 12a and the through hole 11a also acts, and the first terminal component 11 and the second terminal component 12 are less likely to be separated. Therefore, according to the present embodiment, the strength (fastening force) of a caulked and joined terminal 10 with respect to the rotational torque T can be increased. Therefore, the performance of the terminal 10 and the semiconductor device 1 can be enhanced, and the customer satisfaction is also enhanced. In addition, as compared with a method for increasing the strength against the rotational torque T by increasing the amount of crushing (the amount of deformation due to pressing) of the tip of the columnar portion 12a, it is possible to avoid occurrence of cracks around the through hole 11a and the like. Further, in the semiconductor device 1, since the terminal 10 is insert-molded in the case 30, the case 30 can hold the terminal 10 when the rotational torque T is applied to the terminal 10, so that the first terminal component 11 and the second terminal component 12 are further less likely to be separated.

In the present embodiment, the columnar portion 12a of the second terminal component 12 is a cylindrical portion. Therefore, the strength of the terminal 10 against the rotational torque T can be increased with a simple configuration in which one end of the second terminal component 12 is processed into the columnar portion 12a having a cylindrical shape as compared with the case where the columnar portion 12a is a polygonal column.

Further, in the present embodiment, the second terminal component 12 may have a female screw hole 12c at an end portion opposite to the columnar portion 12a. As a result, even if the rotational torque T is applied to the second terminal component 12 when the screw 60 is fastened to the female screw hole 12c, the first terminal component 11 and the second terminal component 12 are less likely to be separated as described above.

In the method for manufacturing the terminal 10 according to the present embodiment, the caulking and joining (the caulking and joining step) includes pressing the columnar portion 12a with the first pressing member P1 having the pressing surface P1a larger than the cross section of the through hole 11a (a first pressing step); and then pressing the columnar portion 12a (the caulked joint portion 12b) toward the through hole 11a with the second pressing member P2 having the pressing surface P2a smaller than the cross section of the through hole 11a (a second pressing step). As a result, since the columnar portion 12a can be made easier to enter the corner portion of the through hole 11a, the gap G2 between the columnar portion 12a and the corner portion of the through hole 11a after the second pressing by the second pressing member P2 can be made smaller than the gap G1 after the first pressing by the first pressing member P1. Therefore, even if the rotational torque T is applied to the terminal 10 (second terminal component 12), the first terminal component 11 and the second terminal component 12 can be further less likely to be separated. In addition, by increasing the contact area between the columnar portion 12a and each wall surface of the through hole 11a, the tensile strength of the second terminal component 12 in the axial direction (the direction opposite to the insertion direction D of the columnar portion 12a) can be increased.

In the method for manufacturing the terminal 10 according to the present embodiment, the pressing surface P2a of the second pressing member P2 is a polygon having a shape similar to the polygon of the cross section of the through hole 11a, and when the columnar portion 12a is pressed toward the through hole 11a by the second pressing member P2 (second pressing step), the columnar portion 12a (caulked joint portion 12b) is pressed toward the through hole 11a by the second pressing member P2 in a direction in which the corner portion of the pressing surface P2a of the second pressing member P2 coincides with the corner portion of the cross section of the through hole 11a. As a result, the columnar portion 12a easily expands toward the corner portion side of the pressing surface P2a, and thus, the columnar portion more easily enters the corner portion of the through hole 11a having a shape similar to the pressing surface P2a. Therefore, even if the rotational torque T is applied to the terminal 10 (second terminal component 12), the first terminal component 11 and the second terminal component 12 can be more hardly separated. Further, by increasing the contact area between the columnar portion 12a and each surface of the through hole 11a, the tensile strength of the second terminal component 12 in the axial direction can be further increased.

In addition, in the method for manufacturing the terminal 10 according to the present embodiment, in pressing the columnar portion 12a (caulked joint portion 12b) toward the through hole 11a by the second pressing member P2 (second pressing step), the second pressing member P2 is made to enter the inside of the through hole 11a. As a result, the tip (pressing surface P2a) of the second pressing member P2 enters the through hole 11a while pushing the columnar portion 12a into the corner portion of the through hole 11a. Therefore, even if the rotational torque T is applied to the terminal 10 (second terminal component 12), the first terminal component 11 and the second terminal component 12 can be more hardly separated. Further, by increasing the contact area between the columnar portion 12a and each surface of the through hole 11a, the tensile strength of the second terminal component 12 in the axial direction can be further increased.

Hereinafter, the invention described in the claims of the originally filed application will be additionally described.

### <Appendix 1>

A terminal including:
a first terminal component having a through hole; and
a second terminal component having a columnar portion inserted into the through hole,
wherein the second terminal component is caulked and joined to the first terminal component at a tip of the columnar portion, and the columnar portion is in contact with a wall surface of the through hole, and
a cross section of the through hole orthogonal to an insertion direction of the columnar portion is polygonal.

### <Appendix 2>

The terminal according to Appendix 1,
wherein the columnar portion of the second terminal component is a cylindrical portion.

### <Appendix 3>

The terminal according to Appendix 1 or 2,
wherein the second terminal component has a female screw hole at an end portion opposite to the columnar portion.

### <Appendix 4>

A method for manufacturing a terminal, the terminal including a first terminal component having a through hole and a second terminal component having a columnar portion inserted into the through hole, the method including:
inserting the columnar portion of the second terminal component into the through hole having a polygonal cross section orthogonal to an insertion direction of the columnar portion; and
bringing the columnar portion into contact with a wall surface of the through hole by caulking and joining the second terminal component to the first terminal component at a tip of the columnar portion inserted into the through hole.

### <Appendix 5>

The method for manufacturing a terminal according to Appendix 4, wherein the caulking and joining includes pressing the columnar portion with a first pressing member having a pressing surface larger than the cross section of the through hole; and then pressing the columnar portion toward the through hole with a second pressing member having a pressing surface smaller than the cross section of the through hole.

### <Appendix 6>

The method for manufacturing a terminal according to Appendix 5, wherein the pressing surface of the second pressing member is a polygon having a shape similar to the polygon of the cross section of the through hole, and
when the columnar portion is pressed toward the through hole by the second pressing member, the columnar portion is pressed toward the through hole by the second pressing member in a direction in which a corner portion of the pressing surface of the second pressing member coincides with a corner portion of the cross section of the through hole.

### <Appendix 7>

The method for manufacturing a terminal according to Appendix 5 or 6, wherein pressing the columnar portion toward the through hole by the second pressing member causes the second pressing member to enter the inside of the through hole.

### <Appendix 8>

A semiconductor device including:
a terminal including a first terminal component having a through hole and a second terminal component having a columnar portion inserted into the through hole;
a semiconductor element electrically connected to the terminal; and
a case which is integrally molded with the terminal in a state where a part of the terminal is exposed and accommodates the semiconductor element,
wherein the second terminal component is caulked and joined to the first terminal component at a tip of the columnar portion and the columnar portion is in contact with a wall surface of the through hole, and
a cross section of the through hole orthogonal to an insertion direction of the columnar portion is polygonal.

As described above, according to the present invention, in the terminal, the method for manufacturing the terminal, and the semiconductor device, the strength of the caulked and joined terminal against the rotational torque can be increased. Therefore, the present invention is particularly useful for a semiconductor element device or the like in which fastening is performed on some terminal components.

What is claimed is:

1. A terminal, comprising:
a first terminal component having a through hole; and
a second terminal component having a columnar portion extending through the through hole, wherein
the second terminal component is mechanically joined to the first terminal component by portions of the columnar portion that are plastically deformed, including a plastically deformed portion that is inside the through hole and in contact with an inner surface of the first terminal component that bounds the through hole, and
a cross section of the through hole orthogonal to a longitudinal axis of the columnar portion is polygonal.

2. The terminal according to claim 1, wherein the plastically deformed portion of the columnar portion that is inside the through hole is a plastic deformation of a cylindrical shape.

3. The terminal according to claim 1, wherein the second terminal component has two opposite ends, the columnar portion being located at one of the two opposite ends, a female screw hole being provided at the other of the two opposite ends.

4. The terminal according to claim 1, wherein a tip of the columnar portion that is exposed outside the first terminal is in direct contact with an outer surface of the first terminal component at an area surrounding the through hole.

5. A method for manufacturing a terminal, the terminal including a first terminal component having a through hole and a second terminal component having a columnar portion extending through the through hole, the method comprising:
inserting the columnar portion of the second terminal component into and through the through hole so that a tip of the columnar portion is exposed outside the first terminal portion, the through hole having a polygonal cross section orthogonal to a longitudinal axis of the through hole; and
bringing an outer surface of the columnar portion into contact with an inner surface of the columnar portion that bounds the through hole, by applying pressure to the tip of the columnar portion so as to plastically deform the columnar portion and thereby mechanically join the second terminal component with the first terminal component.

6. The method for manufacturing a terminal according to claim 5, wherein the mechanical joining includes pressing the columnar portion at the tip thereof toward the through hole by a first pressing member having a pressing surface larger than the cross section of the through hole; and then pressing the columnar portion at the tip thereof toward the through hole by a second pressing member having a pressing surface smaller than the cross section of the through hole.

7. The method for manufacturing a terminal according to claim 6, wherein the pressing surface of the second pressing member is polygonal with a shape similar to the polygonal cross section of the through hole, and
the pressing the columnar portion at the tip thereof toward the through hole by the second pressing member includes setting corner portions of the pressing surface of the second pressing member to coincide with corner portions of the cross section of the through hole.

8. The method for manufacturing a terminal according to claim 6, wherein the pressing the columnar portion at the tip thereof toward the through hole by the second pressing member includes pressing the second pressing member to become embedded in the columnar portion at a position inside the through hole.

9. A semiconductor device, comprising:
a terminal including a first terminal component having a through hole and a second terminal component having a columnar portion extending through the through hole;
a semiconductor element electrically connected to the terminal; and
a case integrally molded with the terminal in a state in which a part of the terminal is exposed and accommodates the semiconductor element, wherein
the second terminal component is plastically deformed so as to be mechanically joined to the first terminal component at the columnar portion, an outer surface of the columnar portion being in contact with an inner surface of the first terminal component that bounds the through hole, and
a cross section of the through hole orthogonal to a longitudinal axis of the through hole is polygonal.
